(19) United States
(12) Patent Application Publication
(10) Pub. No.: US 2026/0259281 A1
(43) Pub. Date: Sep. 3, 2026

(54) ELECTRIC VEHICLE ADAPTER INSPECTION DEVICE FOR DETERMINING THE HEALTH OF AN ELECTRIC VEHICLE CHARGING ADAPTER

(71) Applicant: GM Global Technology Operations LLC, Detroit, MI (US)

(72) Inventors: Christopher Boehm, Joelton, TN (US); Omar Munoz Ramirez, Sterling Heights, MI (US); Alexander T. Marlow, Center Line, MI (US); James C. Gibbs, Brighton, MI (US); Aniket P. Kothari, Rochester Hills, MI (US)

(21) Appl. No.: 19/068,433

(22) Filed: Mar. 3, 2025

(51) Int. Cl. G01R 31/66; B60L 53/16; B60L 53/60; H01R 13/66

(52) U.S. Cl. CPC G01R 31/66; B60L 53/16; B60L 53/60; H01R 13/6683

(57) ABSTRACT

An electric vehicle adapter inspection device for determining the health of an electric vehicle charging adapter includes an inlet, a coupler, and a go/no-go mechanism. The inlet includes a first sensor and a second sensor that have voltage sensor functionality when the device is powered by a low voltage current and have voltage sensor functionality, ammeter functionality, and temperature sensor functionality when the device is powered by a high voltage current. The inlet further includes a third sensor that has voltage sensor functionality. The coupler includes a fourth sensor and a fifth sensor that have temperature sensor functionality when the device is powered by a high voltage current. The go/no-go mechanism determines the health of the electric vehicle charging adapter based upon the measurements of the sensors, comparing the measurements to either each other, a range of stored acceptable values, or a threshold depending on the unit measured.

### INTRODUCTION

The present disclosure relates to using an electric vehicle adapter inspection device for determining the health of an electric vehicle charging adapter.

Electric vehicles may utilize one of many different charging standards with respect to charging the batteries within the electric vehicle (i.e. SAE J1772, North American Charging System (NACS), CHAdeMO, Combined Charging System (CCS), GB/T). However, an electric vehicle may not be able to arrive at a charging station that utilizes the same charging standard before the vehicle would need to be recharged to continue vehicle operation. Electric vehicle charging adapters can then be used to adapt one charging standard to another so an electric vehicle can charge at any charging station, regardless of whether the electric vehicle uses a different charging standard from the charging station.

Thus, there is a need to create an electric vehicle adapter inspection device to determine the health of the electric vehicle charging adapter to verify the electric vehicle charging adapter's continued functionality.

### SUMMARY

According to several aspects, an electric vehicle adapter inspection device for determining the health of an electric vehicle charging adapter is provided. The electric vehicle adapter inspection device may include an inlet wherein a charging station-side of the electric vehicle charging adapter is attached, a coupler that is attached to a vehicle-side of the electric vehicle charging adapter; and a go/no-go mechanism for determining the health of the electric vehicle charging adapter.

In an additional aspect of the present disclosure, the electric vehicle charging adapter is attached to the inlet and the coupler to complete a circuit.

In another aspect of the present disclosure, the inlet may further include a first sensor, a second sensor, and a third sensor.

In an additional aspect of the present disclosure, the first sensor and the second sensor are voltage sensors when the electric vehicle adapter inspection device is powered by a low voltage direct current.

In another aspect of the present disclosure, the first sensor and the second sensor are voltage sensors, ammeters, and temperature sensors when the electric vehicle adapter inspection device is powered by a high voltage direct current.

In an additional aspect of the present disclosure, the coupler further comprises a fourth sensor and a fifth sensor that are both temperature sensors.

In another aspect of the present disclosure, the third sensor has voltage sensor functionality when the electric vehicle adapter inspection device is powered by a low voltage direct current and a high voltage direct current.

In an additional aspect of the present disclosure, the health of the electric vehicle charging adapter is determined to be “good” by the go/no-go mechanism when the absolute value of a voltage measured across a second resistor by the second sensor subtracted from a voltage measured across a first resistor by the first sensor is less than or equal to a voltage threshold.

In another aspect of the present disclosure, the health of the electric vehicle charging adapter is determined to be “good” by the go/no-go mechanism when a voltage measured across a first resistor by the first sensor and a voltage measured across a second resistor by the second sensor fall within a range of acceptable voltage values for a specific electric vehicle charging adapter within memory in the electric vehicle adapter inspection device.

In an additional aspect of the present disclosure, the health of the electric vehicle charging adapter is determined to be “good” by the go/no-go mechanism when an amperage measured across a first resistor by the first sensor is equal to an amperage measured across a second resistor by the second sensor.

In another aspect of the present disclosure, the health of the electric vehicle charging adapter is determined to be “good” by the go/no-go mechanism when an amperage measured across a first resistor by the first sensor and an amperage measured across a second resistor by the second sensor fall within a range of acceptable amperage values for a specific electric vehicle charging adapter within memory in the electric vehicle adapter inspection device.

In an additional aspect of the present disclosure, the health of the electric vehicle charging adapter is determined to be “good” by the go/no-go mechanism when measured temperature increases of the electric vehicle charging adapter by the first sensor, the second sensor, the fourth sensor, and the fifth sensor respectively are all less than or equal to a temperature threshold.

In another aspect of the present disclosure, the health of the electric vehicle charging adapter is determined to be “good” by the go/no-go mechanism when a voltage measured across a third resistor and a voltage measured across a fourth resistor by the third sensor are equal.

In another aspect of the present disclosure, the health of the electric vehicle charging adapter is determined to be “good” by the go/no-go mechanism when a voltage measured across a fourth resistor by the third sensor after a heating mechanism heats the electric vehicle charging adapter to a temperature that allows a overtemperature charge current-limiting mechanism disposed within the electric vehicle charging adapter to trigger shifts to a value that is less than a voltage measured across the fourth resistor by the third sensor before the heating mechanism heats the electric vehicle charging adapter to verify that the overtemperature charge current-limiting mechanism has triggered.

In an additional aspect of the present disclosure, the electric vehicle adapter inspection device may be disposed within an electric vehicle.

In another aspect of the present disclosure, the electric vehicle adapter inspection device may be disposed within a rental unit enclosure.

In an additional aspect of the present disclosure, the electric vehicle adapter inspection device may be disposed within a charging station.

According to several aspects, an electric vehicle adapter inspection device for determining the health of an electric vehicle charging adapter is provided. The electric vehicle adapter inspection device may include an inlet wherein a charging station-side of the electric vehicle charging adapter is attached comprising a first sensor, a second sensor, and a third sensor that are voltage sensors. The electric vehicle adapter inspection device may further include a coupler that is attached to a vehicle-side of the electric vehicle charging adapter. The electric vehicle adapter inspection device may further include a go/no-go mechanism for determining the health of the electric vehicle charging adapter. The electric vehicle adapter inspection device may further include a plurality of signal lights that indicate the health of the electric vehicle charging adapter based on the determination of health of the electric vehicle charging adapter by the go/no-go mechanism. The electric vehicle adapter inspection device is powered by a low voltage direct-current electric current. The health of the electric vehicle charging adapter is determined to be “good” by the go/no-go mechanism when the absolute value of a voltage measured across a second resistor by the second sensor subtracted from a voltage measured across a first resistor by the first sensor is less than or equal to a voltage threshold or the voltage measured across the first resistor by the first sensor and the voltage measured across the second resistor by the second sensor fall within a range of acceptable voltage values for a specific electric vehicle charging adapter within memory in the electric vehicle adapter inspection device.

According to several aspects, an electric vehicle adapter inspection device for determining the health of an electric vehicle charging adapter is provided. The electric vehicle adapter inspection device may include an inlet wherein a charging station-side of the electric vehicle charging adapter is attached comprising a first sensor and a second sensor are voltage sensors, ammeters, and temperature sensors and the inlet may further include a third sensor that is a voltage sensor. The electric vehicle adapter inspection device may further include a coupler that is attached to a vehicle-side of the electric vehicle charging adapter comprising a fourth sensor and a fifth sensor that are temperature sensors. The electric vehicle adapter inspection device may further include a go/no-go mechanism for determining the health of the electric vehicle charging adapter. The electric vehicle adapter inspection device may further include a plurality of signal lights that indicate the health of the electric vehicle charging adapter based on the determination of health of the electric vehicle charging adapter by the go/no-go mechanism. The health of the electric vehicle charging adapter is determined to be “good” by the go/no-go mechanism when the absolute value of a voltage measured across a second resistor by the second sensor subtracted from a voltage measured across a first resistor by the first sensor is less than or equal to a voltage threshold, an amperage measured across the first resistor by the first sensor is equal to an amperage measured across the second resistor by the second sensor, measured temperature increases of the electric vehicle charging adapter measured by the first sensor, the second sensor, the fourth sensor, and the fifth sensor are all less than or equal to a temperature threshold, a voltage measured across a third resistor and a voltage measured across a fourth resistor by the third sensor are equal, and a voltage measured across the fourth resistor by the third sensor after a heating mechanism heats the electric vehicle charging adapter to a temperature that allows a overtemperature charge current-limiting mechanism disposed within the electric vehicle charging adapter to trigger shifts to a value that is less than a voltage measured across the fourth resistor by the third sensor before the heating mechanism heats the electric vehicle charging adapter to verify that the overtemperature charge current-limiting mechanism has triggered. The electric vehicle adapter inspection device is powered by a high voltage direct-current electric current.

In another aspect of the present disclosure, the electric vehicle adapter inspection device may be disposed within an electric vehicle.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic diagram of a system for the use of an electric vehicle adapter inspection device to determine the health of an electric vehicle charging adapter according to an exemplary embodiment;

FIG. 2 is a diagram of an electric vehicle adapter inspection device for determining the health of an electric vehicle charging adapter according to an exemplary embodiment;

FIG. 3 is a diagram of the circuitry between a coupler, the electric vehicle charging adapter, and an inlet when the electric vehicle adapter inspection device is powered by a low voltage direct current according to an exemplary embodiment;

FIG. 4 is a diagram of the circuitry between the coupler, the electric vehicle charging adapter, and the inlet when the electric vehicle adapter inspection device is powered by a high voltage direct current according to an exemplary embodiment;

FIG. 5 is a flowchart demonstrating the method for determining the health of the electric vehicle charging adapter utilized by a go/no-go mechanism when the electric vehicle adapter inspection device is powered by a low voltage direct current according to an exemplary embodiment;

FIG. 6A is a first part of a flowchart demonstrating the method for determining the health of the electric vehicle charging adapter utilized by the go/no-go mechanism when the electric vehicle adapter inspection device is powered by a high voltage direct current according to an exemplary embodiment;

FIG. 6B is a second part of a flowchart demonstrating the method for determining the health of the electric vehicle charging adapter utilized by the go/no-go mechanism when the electric vehicle adapter inspection device is powered by a high voltage direct current according to an exemplary embodiment;

FIG. 6C is a third part of a flowchart demonstrating the method for determining the health of the electric vehicle charging adapter utilized by the go/no-go mechanism when the electric vehicle adapter inspection device is powered by a high voltage direct current according to an exemplary embodiment;

FIG. 7 is a diagram showing how the electric vehicle adapter inspection device communicates with an external device and a rental unit enclosure according to an exemplary embodiment;

FIG. 8 is a flowchart for a method of determining the health of an electric vehicle charging adapter using the electric vehicle adapter inspection device within the rental unit enclosure according to an exemplary embodiment;

FIG. 9 is a flowchart for a method of determining the health of the electric vehicle charging adapter using a charging station according to an exemplary embodiment;

FIG. 10 is a flowchart for a method of determining the health of the electric vehicle charging adapter using a vehicle according to an exemplary embodiment; and

FIG. 11 is a flowchart for a method of determining the health of the electric vehicle charging adapter using the electric vehicle adapter inspection device as a standalone device according to an exemplary embodiment.

### DETAILED DESCRIPTION

The following description is merely exemplary in nature and is not intended to limit the present disclosure, application, or uses.

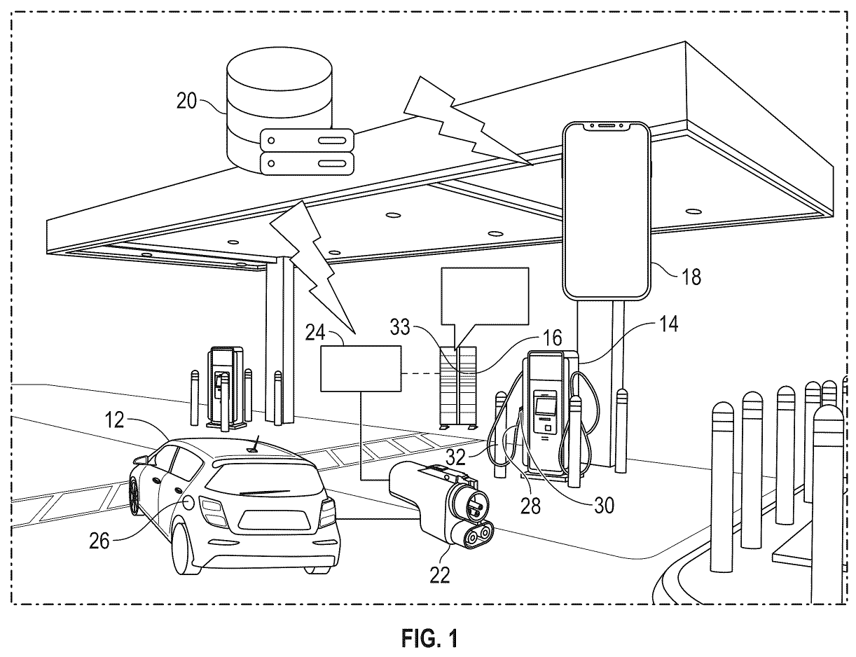

Referring to FIG. 1, a schematic diagram of a system for the use of an electric vehicle adapter inspection device to determine the health of an electric vehicle charging adapter is generally indicated by reference number 10. The system 10 generally includes a vehicle 12, a charging station 14, a rental unit enclosure 16, an external device 18, a back-office computing platform 20, an electric vehicle charging adapter 22, and an electric vehicle adapter inspection device 24. It should be appreciated that the “health” of the electric vehicle charging adapter 22 refers to the maintained functionality of the electric vehicle charging adapter 22 and the electric vehicle charging adapter's 22 components.

The vehicle 12 is a land vehicle such as a car, truck, etc. that can be operated by a user or by an autonomous driving module. The vehicle 12 may have various levels of driving automation, including Level Five, Level Four, Level Three, and Level Two automation. For example, a Level Five system indicates “full automation,” referring to the full-time performance by an automated driving system of aspects of the dynamic driving task under a number of roadway and environmental conditions that can be managed by a human driver. A Level Four system indicates “high automation,” referring to the driving mode-specific performance by an automated driving system of aspects of the dynamic driving task, even if a human driver does not respond appropriately to a request to intervene. In Level Three vehicles, the vehicle systems perform the entire dynamic driving task (DDT) within the area that it is designed to do so. The vehicle operator is only expected to be responsible for the DDT-fallback when the vehicle 12 essentially “asks” the driver to take over if something goes wrong or the vehicle is about to leave the zone where it is able to operate. In Level Two vehicles, systems provide steering, brake/acceleration support, lane centering, and adaptive cruise control. However, even if these systems are activated, the vehicle operator at the wheel must be driving and constantly supervising the automated features. The vehicle 12 may include various actuator devices (not shown) used to achieve the above-described levels of automation. The actuator devices control one or more vehicle features including, but not limited to, a propulsion system, a transmission system, a steering system, and a brake system (not shown). In various embodiments, the vehicle features may further include interior and/or exterior vehicle features such as, but are not limited to, doors, a trunk, and cabin features such as air, music, lighting, etc. The vehicle 12 comprises a screen for display purposes and a human-machine interface to allow a user to send and receive communications to and from the electric vehicle adapter inspection device, which is described in greater detail below. The vehicle 12 also comprises a vehicle inlet 26, which is a port where a charging cable can be attached to the vehicle 12 for the purpose of charging the vehicle 12. It should be appreciated that the vehicle 12 is an electric vehicle, meaning that the vehicle 12 is powered by at least one electric motor using energy stored in rechargeable batteries. The vehicle 12 may comprise a go/no-go mechanism of an electric vehicle adapter inspection device, which is described in greater detail below.

The charging station 14 is equipment that supplies electric energy for the purpose of recharging the rechargeable batteries within the vehicle 12. The charging station 14 may comprise an electric vehicle adapter inspection device, which is described in greater detail below. The charging station 14 comprises a screen for display purposes and a human-machine interface to allow a user to send and receive communications to and from the electric vehicle adapter inspection device, which is described in greater detail below. In a non-limiting list of examples, the charging station 14 may be a Level 1 Charging Station, a Level 2 Charging Station, a Direct Current (DC) Fast Charging Station, or a General Motors (GM) Energy Home Charger.

The charging station coupler 28 establishes a reliable electrical connection between the charging station 14 and the vehicle 12 for the purpose of charging the vehicle 12. The charging station coupler 28 may include a connector 30, a cable 32, a locking mechanism (not shown), insulation (not shown), and a cooling system (not shown). The connector 30 physically attaches the charging station coupler 28 to the vehicle inlet 26 of the vehicle 12. The connector 30 may be one of many charging standards, with a non-limiting list of examples being SAE J1772(Type 1), Mennekes (Type 2), CHAdeMO, Combined Charging System (CCS), NACS, GB/T, and Megawatt Charging System (MCS). The connector includes pins, which establish the electrical connection between the charging station 14 and the vehicle 12. The cable 32 carries an electrical current from the electric vehicle adapter inspection device 24 to the electric vehicle charging adapter 22 while also physically linking the charging station coupler 28 to the electric vehicle adapter inspection device 24. The locking mechanism ensures a secure attachment and prevents accidental disconnection between the electric vehicle adapter inspection device 24 and the electric vehicle charging adapter 22. The insulation protects the internal components, including the connector 30, locking mechanism, and cooling system from external environmental factors that could damage the internal components of the charging station coupler 28. The cooling system allows the charging station coupler 28 to dissipate heat while the charging station coupler 28 is attached to the electric vehicle charging adapter 22, preventing overheating.

The rental unit enclosure 16 is a locker or storage location to store the electric vehicle charging adapter 22 while it is not in use. The electric vehicle adapter inspection device 24 is disposed within the rental unit enclosure 16 so the health of the electric vehicle charging adapter 22 can be determined in between uses of the electric vehicle charging adapter 22. The rental unit enclosure 16 comprises a door 33 that can be opened to remove the electric vehicle charging adapter 22 from the rental unit enclosure 16 and can be closed to secure the electric vehicle charging adapter 22 within the rental unit enclosure 16 while the electric vehicle charging adapter 22 is not in use. In a non-limiting list of examples, the rental unit enclosure 16 can be an Amazon Locker or a Fastenal FastVend.

The external device 18 is a device that communicates outgoing data to the electric vehicle adapter inspection device 24. The external device 18 comprises a screen for display purposes and a human-machine interface to allow a user to send and receive communications to and from the electric vehicle adapter inspection device 24. While the external device 18 is illustrated as a mobile phone for the purposes of this disclosure, it should be appreciated that the external device 18 may take various forms. For example, the external device 18 may be a tablet, a smart watch, a laptop, or a desktop computer. The external device 18 comprises a camera 34. The camera 34 uses light to capture images of the electric vehicle charging adapter 22 to determine the optical health of the electric vehicle charging adapter 22. In a non-limiting list of examples, the camera 34 may be a Wide-Angle Camera, an Ultra-Wide-Angle Camera, a Telephoto Camera, a Macro Camera, a Monochrome Camera, and a Periscope Camera.

The back-office computing platform 20 is software that manages and automates the internal operations of a business, particularly internal operations of a business relating to the electric vehicle adapter inspection device 24. The back-office computing platform communicates information between the external device 18 and the electric vehicle adapter inspection device 24. The back-office computing platform can be housed in a physical data center on physical servers or can be hosted using cloud computing over the internet with remote servers. The back-office computing platform 20 can automate routine tasks, track and provide real-time data. The back-office computing platform 20 includes an algorithm that can analyze images taken by the camera 34 of the electric vehicle charging adapter 22 to determine the optical health of the electric vehicle charging adapter 22. In a non-limiting list of further examples, the back-office computing platform 20 can handle inventory management, accounting, finance, human resources, supply chain management, data management, workflow automation, and customer relationship management.

The electric vehicle charging adapter 22 allows the vehicle 12 to connect to the charging station 14 when the charging station 14 uses a different connection standard than the one used for the vehicle 12. In a non-limiting list of examples, the electric vehicle charging adapter 22 may be a CHAdeMO Adapter, a Combined Charging System (CCS) Adapter, a North American Charging Standard (NACS) to J1772Adapter, a J1772 to NACS Adapter, a NACS to CSS Adapter, and a CSS to NACS Adapter. The electric vehicle charging adapter 22 generally includes a overtemperature charge current-limiting mechanism 37.

The overtemperature charge current-limiting mechanism 37 is a mechanism within the electric vehicle charging adapter 22 that prevents the electric vehicle charging adapter 22 from overheating. The overtemperature charge current-limiting mechanism 37 prevents overheating by monitoring and detecting a threshold temperature, which, once achieved within the electric vehicle charging adapter 22, allows the overtemperature charge current-limiting mechanism 37 to communicate with a power source (i.e. the vehicle 12 and the charging station 14) to reduce the power output of the electric vehicle adapter inspection device 24. In a non-limiting example, the overtemperature charge-current limiting mechanism 37 may be a thermal derate switch. When the overtemperature charge-current limiting mechanism 37 is a thermal derate switch, in a non-limiting list of examples, the overtemperature charge current-limiting mechanism 37 may be a bimetallic disc switch, a thermal reed switch, a mercury switch, a rod and tube switch, or a gas-actuated/vapor-tension switch.

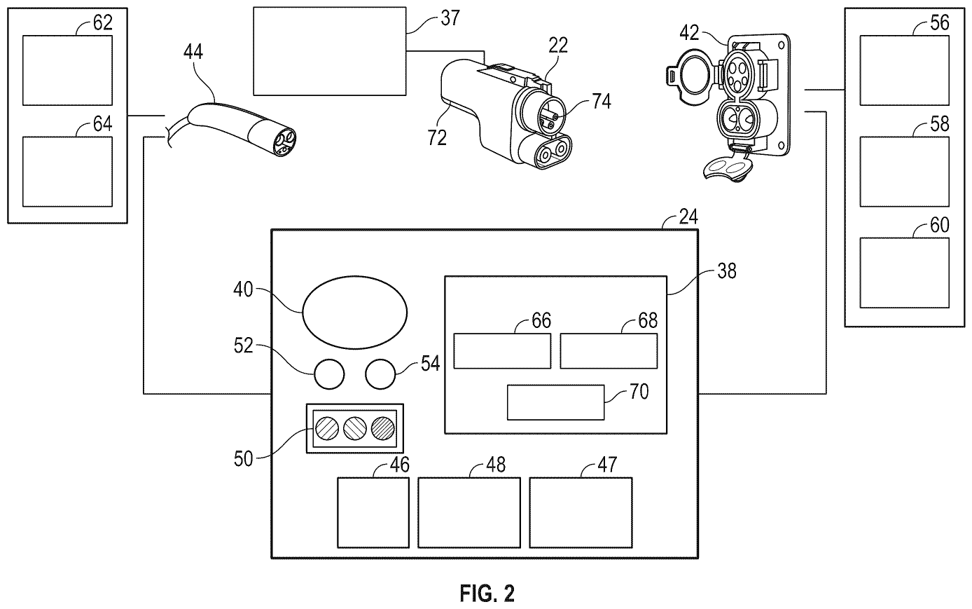

Referring to FIG. 2, a diagram of an electric vehicle adapter inspection device 24 for determining the health of an electric vehicle charging adapter 22 is shown. The electric vehicle adapter inspection device 24 generally includes a controller 38, a cellular transceiver 40, an inlet 42, a coupler 44, a timer 46, a heating mechanism 47, a go/no-go mechanism 48, and a plurality of signal lights 50. It should be appreciated that in an exemplary embodiment where the electric vehicle adapter inspection device 24 is not disposed within another device (a standalone embodiment), such as the vehicle 12, the charging station 14, or the rental unit enclosure 16, the electric vehicle adapter inspection device 24 includes a power button 52 which can be pressed to power the device on and off. The standalone embodiment also includes an “initiate test” button 54, which initiates the determination of the health of the electric vehicle charging adapter 22 by the electric vehicle adapter inspection device 24.

It should be appreciated that when the electric vehicle adapter inspection device 24 is powered by a low voltage direct current, the electric vehicle adapter inspection device 24 is powered by around or below 1 kilovolt while an electric charging moving through the electric vehicle adapter inspection device 24 is moving in one direction. It should also be appreciated that when the electric vehicle adapter inspection device 24 is powered by a high voltage direct current, the electric vehicle adapter inspection device 24 is powered by around 1000 volts while an electric charge moving through the electric vehicle adapter inspection device 24 is moving in one direction.

The controller 38 is a non-generalized, electronic control device having a preprogrammed digital computer or processor 66, memory 68, and input and output ports 70. The processor 66 may be a custom made or commercially available processor, a central processing unit (CPU), a graphics processing unit (GPU), an auxiliary processor among several processors associated with the controller 38, a semiconductor-based microprocessor (in the form of a microchip or chip set), a macroprocessor, a combination thereof, or generally a device for executing instructions. The memory 68 is used to store data such as control logic, software applications, instructions, computer code, data, lookup tables, etc. The memory 68 includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device. Computer code includes any type of program code, including source code, object code, and executable code. In an example where the electric vehicle adapter inspection device 24 is powered by a low voltage direct current, the memory 68 stores a list of acceptable resistance levels of particular electrical pathways within a particular electric vehicle charging adapter. In an example where the electric vehicle adapter inspection device 24 is powered by a high voltage direct current, the memory 68 stores a list of acceptable resistance levels and amperage levels of particular electrical pathways within a particular electric vehicle charging adapter. The processor 66 is configured to execute the code or instructions, including a method for determining the health of the electric vehicle charging adapter 22.

The cellular transceiver 40 is configured to wirelessly communicate with an external device 18 using Wi-Fi protocols under IEEE 802.11x standards. The cellular transceiver 40 may also be configured to wirelessly communicate using cellular data communication under GSMA standards, such as SGP.02, SGP.22, SGP.32, and the like. Suitably, the go/no-go mechanism 48 may further include an embedded universal integrated circuit card (eUICC) configured to store at least one cellular connectivity configuration profile, for example, an embedded subscriber identity module (eSIM) profile. The cellular transceiver 40 is further configured to communicate via a personal area network (e.g., BLUETOOTH), near-field communication (NFC), and/or any additional type of radiofrequency communication.

The inlet 42 is a port which facilitates a charging station-side 74 of the electric vehicle charging adapter 22 to be attached to the electric vehicle adapter inspection device 24, completing a circuit between itself, the coupler 44, and the electric vehicle charging adapter 22. The charging station-side 74 of the electric vehicle charging adapter 22 is the side of the electric vehicle charging adapter 22 that is attached to the inlet 42. The circuit allows the electric vehicle adapter inspection device 24 to determine the health of the electric vehicle charging adapter 22 by performing tests on the electric vehicle charging adapter 22. The inlet 42 may include power lines (not shown), which deliver electricity from the coupler 44 through the electric vehicle charging adapter 22 to the electric vehicle adapter inspection device 24. The inlet 42 comprises a first sensor 56, a second sensor 58, and a third sensor 60.

The first sensor 56 is situated within the inlet 42 of the electric vehicle adapter inspection device 24 and is used to determine the health of the electric vehicle charging adapter 22. In an exemplary embodiment where the electric vehicle adapter inspection device 24 is powered by a low voltage direct current, the first sensor 56 is a voltage sensor, where the first sensor 56 measures the voltage across an adjacent transistor to determine the health of the electric vehicle charging adapter 22. In a non-limiting list of examples, the voltage sensor functionality could be a resistive type voltage sensor or a capacitive type voltage sensor. Once the voltage level is measured, the first sensor 56 communicates the measurements to the go/no-go mechanism 48. In an exemplary embodiment where the electric vehicle adapter inspection device 24 is powered by a high voltage direct current, the first sensor 56 is a voltage sensor, an ammeter, and a temperature sensor. The ammeter functionality of the first sensor 56 is used to measure the amperage across an adjacent resistor to determine the health of the electric vehicle charging adapter 22. In a non-limiting list of examples, the ammeter functionality could be an analog ammeter or a digital ammeter. Once the amperage of the particular electrical pathways of the circuit are measured by the first sensor 56, the first sensor 56 communicates the measurements to the go/no-go mechanism 48. The temperature sensor functionality of the first sensor 56 is used to measure the temperature of the electric vehicle charging adapter 22 as a test to determine the health of the electric vehicle charging adapter 22. In a non-limiting list of examples, the temperature sensor functionality may be a thermocouple, a thermistor, a resistance temperature detector, a thermometer integrated circuit, or an infrared (IR) sensor. Once the temperature of the electric vehicle charging adapter 22 is measured by the first sensor 56, the first sensor 56 communicates the measurements to the go/no-go mechanism 48.

The second sensor 58 is situated within the inlet 42 of the electric vehicle adapter inspection device 24 and is used to determine the health of the electric vehicle charging adapter 22. It should be appreciated that the second sensor 58 is identical to and shares functionality with the first sensor 56.

The third sensor 60 is situated within the inlet 42 of the electric vehicle adapter inspection device 24 and is used to determine the health of the electric vehicle charging adapter 22. It should be appreciated that the functionality of the third sensor 60 is identical to and is shared with the voltage sensor functionality of the first sensor 56.

The coupler 44 is attached to a vehicle-side 72 of the electric vehicle charging adapter 22, completing a circuit between itself, the inlet 42, and the electric vehicle charging adapter 22. The vehicle-side 72 of the electric vehicle charging adapter 22 is the side of the electric vehicle charging adapter 22 that is attached to the coupler 44. The circuit allows the electric vehicle adapter inspection device 24 to determine the health of the electric vehicle charging adapter 22 by performing tests on the electric vehicle charging adapter 22. It should be appreciated that the coupler 44 shares its form and functionality with the charging station coupler 28. The coupler 44 also comprises a fourth sensor 62 and a fifth sensor 64.

The fourth sensor 62 is situated within the coupler 44 of the electric vehicle adapter inspection device 24 and is used to determine the health of the electric vehicle charging adapter 22. It should be appreciated that the functionality of the fourth sensor 62 is identical to and is shared with the temperature sensor functionality of the first sensor 56. It should also be appreciated that the fourth sensor 62 is only utilized when the electric vehicle adapter inspection device 24 is powered by a high voltage direct current.

The fifth sensor 64 is situated within the coupler 44 of the electric vehicle adapter inspection device 24 and is identical to and shares functionality with the fourth sensor 62.

The timer 46 tracks the amount of time that has elapsed from an initial starting point in time. In a non-limiting list of examples, the timer 46 may be a mechanical timer, an electromechanical timer, or a digital timer.

The heating mechanism 47 provides heat to the electric vehicle charging adapter 22 to a temperature that would allow the overtemperature charge current-limiting mechanism 37 37 to trigger. In a non-limiting list of examples, the heating mechanism may utilize conduction heating, convection heating, thermal interface materials (TIMs), and heat pipes.

The go/no-go mechanism 48 follows a decision-making process to determine whether the electric vehicle charging adapter 22 is healthy based upon the outcome of at least one test the electric vehicle adapter inspection device 24 performs on the electric vehicle charging adapter 22. The go/no-go mechanism 48 is disposed within the processor 66.

The plurality of signal lights 50 indicate the determination of the health of the electric vehicle charging adapter 22. In a non-limiting example, the plurality of signal lights 50 comprises three lights: a red light, a yellow light, and a green light. The red light indicates that the health of the electric vehicle charging adapter 22 is “poor” and that the electric vehicle charging adapter 22 is not functioning properly. The yellow light indicates that the health of the electric vehicle charging adapter 22 is indeterminate and that there may be further inspection of the electric vehicle charging adapter 22 required to determine its health. The green light indicates that the health of the electric vehicle charging adapter 22 is good and that the electric vehicle charging adapter 22 is functioning properly. It should be appreciated that the plurality of signal lights 50 may comprise more than the red, yellow, and green lights described, and may comprise as few as two lights.

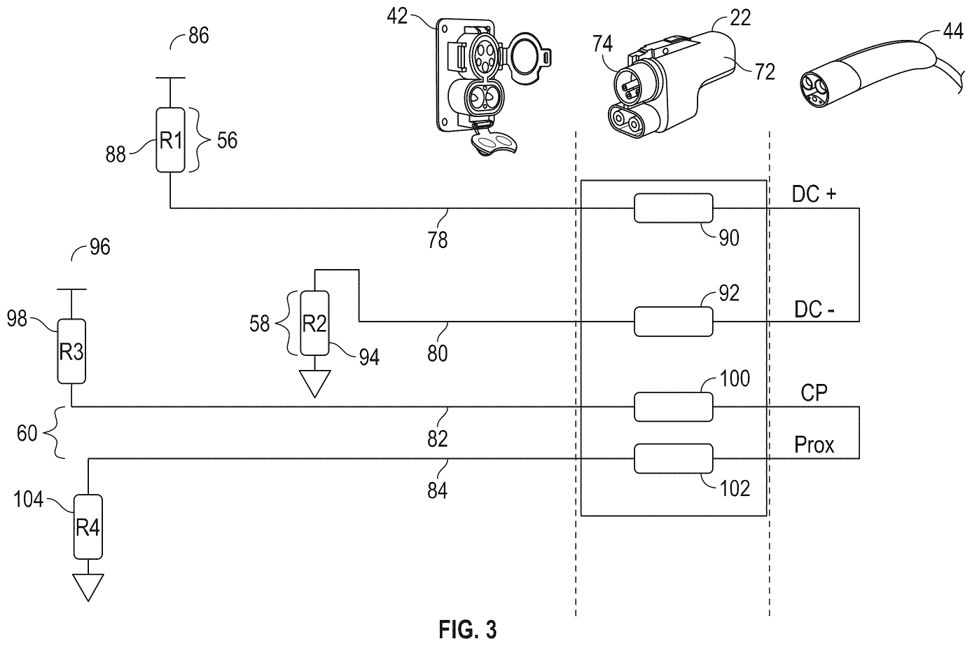

Referring to FIG. 3, a diagram of the circuitry between the coupler 44, the electric vehicle charging adapter 22, and the inlet 42 when the electric vehicle adapter inspection device 24 is powered by a low voltage direct current is generally indicated by reference number 76. The low voltage circuitry 76 comprises a direct current positive (DC+) power line 78, a direct current negative (DC−) power line 80, a control pilot power line 82, and a proximity power line 84.

The DC+ power line 78 carries a positive direct current from a first voltage supply 86 within the inlet 42 through a first resistor 88 within the inlet 42. The first resistor 88 controls the current flow along the DC+ power line 78, preventing damage to the DC+ power line 78 due to an excessive current. The positive direct current continues through a first resistance equalizer 90 within the electric vehicle charging adapter 22 to the coupler 44. The first resistance equalizer 90 corrects amplitude and phase errors detected along the DC+ power line 78. The DC− power line 80 carries a negative direct current from the coupler 44 through a second resistance equalizer 92 within the electric vehicle charging adapter 22. The second resistance equalizer 92 corrects amplitude and phase errors detected along the DC− power line 80. The negative direct current continues through a second resistor 94 within the inlet 42. The second resistor 94 controls the current flow along the DC− power line 80, preventing damage to the DC− power line 80 due to an excessive current. The first sensor 56 and a second sensor 58 are situated directly beside the first resistor 88 and the second resistor 94 respectively. The first sensor 56 and the second sensor 58 are both voltage sensors.

The control pilot power line 82 is used for communication between the electric vehicle adapter inspection device 24 and the electric vehicle charging adapter 22. A non-limiting list of examples of the communication comprises indicating the status of the connection between the electric vehicle adapter inspection device 24 and the electric vehicle charging adapter 22 and detecting a circuitry fault, disconnecting the power between the electric vehicle adapter inspection device 24 and the electric vehicle charging adapter 22 if necessary. The control pilot power line 82 carries an electrical current from a second voltage supply 96 through a third resistor 98 within the inlet 42. The third resistor 98 controls the electrical current along the control pilot power line 82, preventing damage to the control pilot power line 82 due to an excessive electrical current.

The electrical current continues through a third resistance equalizer 100 within the electric vehicle charging adapter 22 to the coupler 44. The third resistance equalizer 100 corrects amplitude and phase errors detected along the control pilot power line 82. The proximity power line 84 is used to determine whether the connector 30 is properly attached to the electric vehicle charging adapter 22 before allowing the DC+ power line 78 and the DC− power line 80 to receive power. The proximity power line 84 carries the electrical current through a fourth resistance equalizer 102 within the electric vehicle charging adapter 22. The fourth resistance equalizer 102 corrects amplitude and phase errors detected along the proximity power line 84. The electrical current continues through a fourth resistor 104 within the inlet 42. The fourth resistor 104 controls the electrical current along the proximity power line 84, preventing damage to the proximity power line 84 due to an excessive electrical current. The third sensor 60 is situated between the third resistor 98 and the fourth resistor 104.

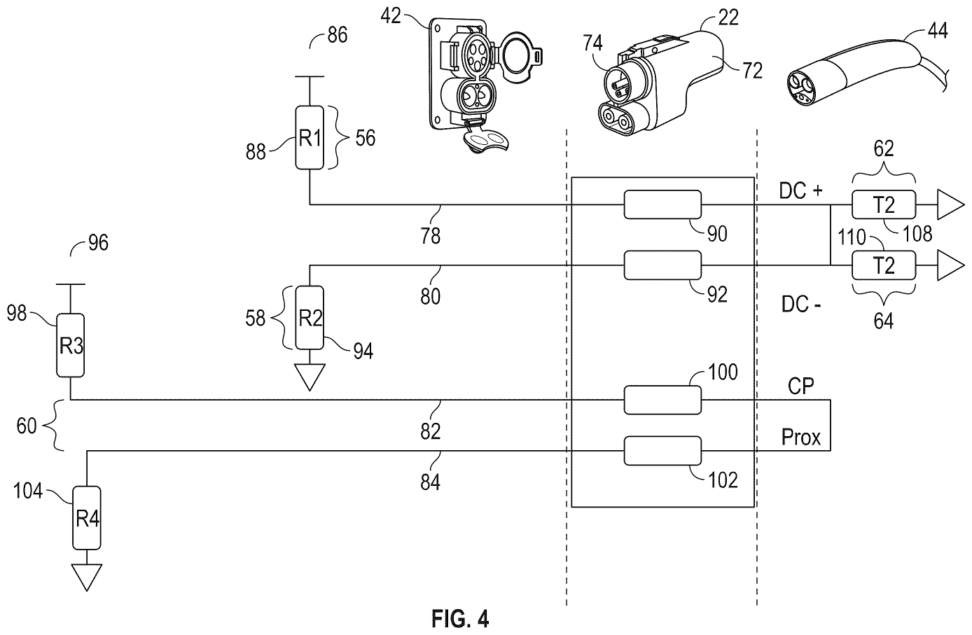

Referring to FIG. 4, a diagram of the circuitry between the coupler 44, the electric vehicle charging adapter 22, and the inlet 42 when the electric vehicle adapter inspection device 24 is powered by a high voltage direct current is generally indicated by reference number 106. The high voltage circuitry 106 comprises the DC+ power line 78, the DC− power line 80, the control pilot power line 82, and the proximity power line 84 that are present within the low voltage circuitry 76, maintaining the same function and configuration as previously described. In this exemplary embodiment, a first transistor 108 and a second transistor 110 are situated within the coupler 44 along the DC+ power line 78 and the DC− power line 80 respectively. The first transistor 108 and the second transistor 110 are used to amplify the respective positive direct current and negative current for the DC+ power line 78 and the DC− power line 80, and in non-limiting examples, the first transistor 108 and the second transistor 110 can be a Bipolar Junction Transistor (BJT) or a Field-Effect Transistor (FET).

The fourth sensor 62 and the fifth sensor 64 are also situated beside the first transistor 108 and the second transistor 110 respectively.

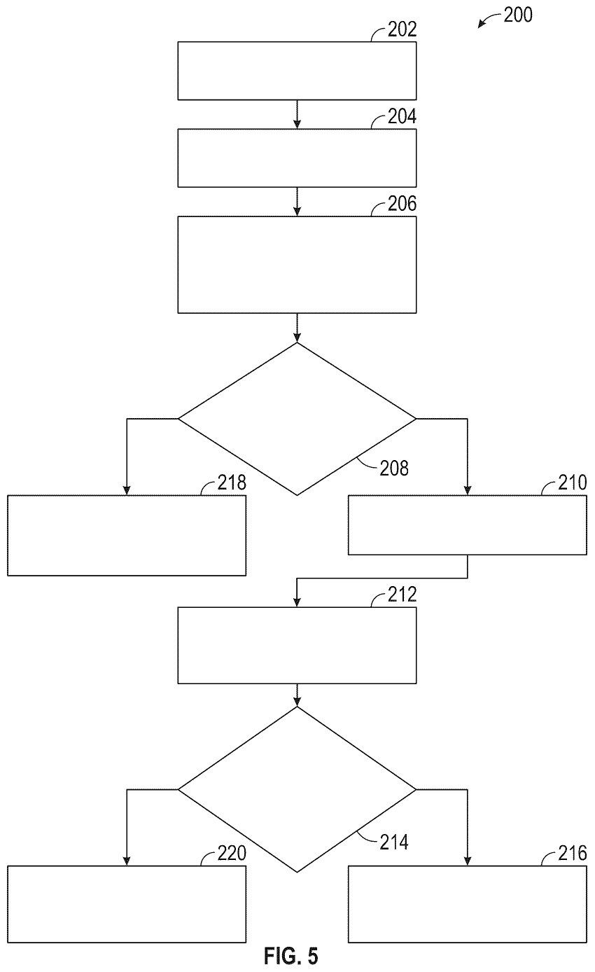

Referring to FIG. 5, a flowchart demonstrating a method for determining the health of the electric vehicle charging adapter 22 utilized by the go/no-go mechanism 48 when the electric vehicle adapter inspection device 24 is powered by a low voltage direct current is generally indicated by reference number 200.

The method 200 begins at step 202, determining the type of electric vehicle charging adapter that is being tested. The method 200 then proceeds to step 204.

At step 204, the first voltage supply 86 is enabled at a low voltage direct current. The method 200 then proceeds to step 206.

At step 206, the first sensor 56 and the second sensor 58 measure the voltage across the first resistor 88 and the voltage across the second resistor 94 respectively. The method 200 then proceeds to step 208.

When the method 200 is comparing the DC+ power line 78 to the DC− power line 80 to determine the health of the electric vehicle charging adapter 22, at step 208, the method 200 compares the absolute value of the voltage measured across the first resistor 88 subtracted from the voltage measured across the second resistor 94 to a voltage threshold. It should be appreciated that the voltage threshold may be determined by a voltage divider that would determine a maximum allowable voltage by calculating a maximum allowable resistance when a maximum current is running through the DC+ power line 78 to the DC− power line 80 where the DC+ power line 78 and the DC− power line 80 are not generating too much heat to overheat the electric vehicle charging adapter 22. It should be appreciated that the voltage threshold may also be determined by comparing the voltage measured across the first resistor 88 and the voltage measured across the second resistor 94 to each other and developing an expected voltage based upon the measured voltage values. When the voltage threshold is greater than the absolute value of the voltage measured across the first resistor 88 subtracted from the voltage measured across the second resistor 94, the method 200 then proceeds to step 210.

When the method 200 uses values stored within memory 68 to determine the health of the electric vehicle charging adapter 22, at step 208, the method 200 compares the voltage measured across the first resistor 88 and the voltage measured across the second resistor 94 to a range of acceptable voltage values in memory 68 for the specific electric vehicle charging adapter being tested. When the voltage measured across the first resistor 88 and the voltage measured across the second resistor 94 fall within the range of acceptable voltage values, the method 200 then proceeds to step 210.

At step 210, the second voltage supply 96 is enabled at a low current. The method 200 then proceeds to step 212.

At step 212, the third sensor 60 measures the voltage across the third resistor 98 and the voltage across the fourth resistor 104. The method 200 then proceeds to step 214.

At step 214, the method 200 compares the value of the voltage measured across the third resistor 98 and the value of the voltage measured across the fourth resistor 104 are equal. When the voltage measured across the third resistor 98 and the voltage measured across the fourth resistor 104 are equal, the method 200 then proceeds to step 216.

At step 216, the electric vehicle adapter inspection device 24 determines that the health of the electric vehicle charging adapter 22 is “good” and the green light from the plurality of signal lights 50 is lit.

Returning to step 208, when the absolute value of the voltage measured across the first resistor 88 subtracted from the voltage measured across the second resistor 94 is greater than the voltage threshold, or when the measured voltage across the first resistor 88 and the second resistor 94 does not fall within the range of acceptable voltage values, the method 200 then proceeds to step 218.

At step 218, the electric vehicle adapter inspection device 24 determines that the health of the electric vehicle charging adapter 22 is “poor” and the red light from the plurality of signal lights 50 is lit.

Returning to step 214, when the voltage measured across the third resistor 98 and the voltage measured across the fourth resistor 104 are unequal, the method 200 then proceeds to step 220.

At step 220, the electric vehicle adapter inspection device 24 determines that the health of the electric vehicle charging adapter 22 is “poor” and the red light from the plurality of signal lights 50 is lit.

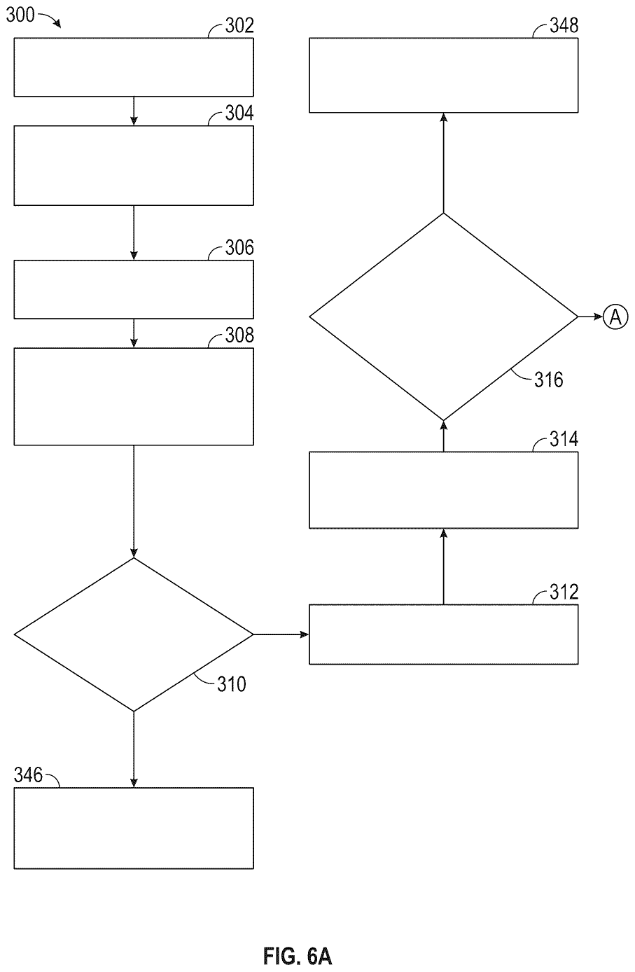

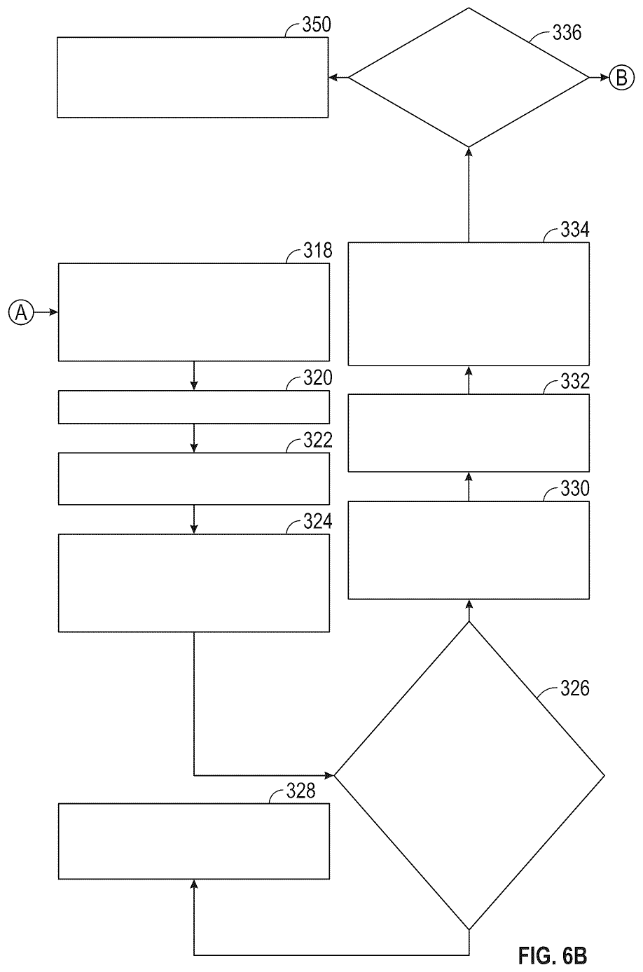

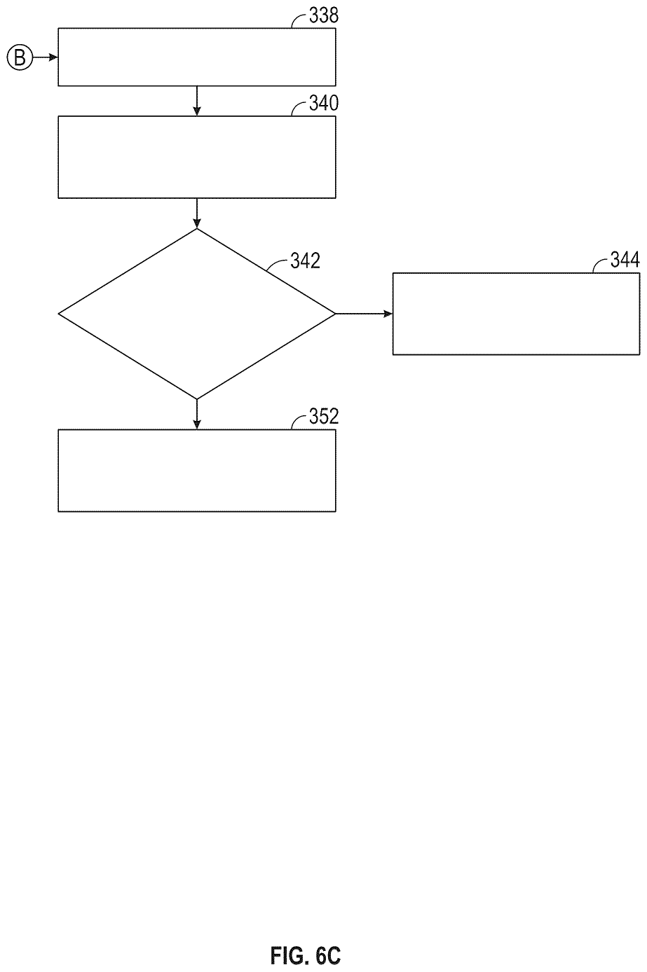

Referring to FIGS. 6A, 6B, and 6C, a flowchart demonstrating a method for determining the health of the electric vehicle charging adapter 22 utilized by the go/no-go mechanism 48 when the electric vehicle adapter inspection device 24 is powered by a high voltage direct current is generally indicated by reference number 300. In this example, it is assumed that the electric vehicle adapter inspection device 24 can be powered by a high voltage direct current.

The method 300 begins at step 302, determining the type of electric vehicle charging adapter that is being tested. The method 300 then proceeds to step 304.

At step 304, the first sensor 56, the second sensor 58, the fourth sensor 62, and the fifth sensor 64 measure a starting temperature and save the starting temperature to memory 68. The method 300 then proceeds to step 306.

At step 306, the first voltage supply 86 is enabled at a low current. The method 300 then proceeds to step 308.

At step 308, the first sensor 56 and the second sensor 58 measure the voltage across the first resistor 88 and the voltage across the second resistor 94 respectively. The method 300 then proceeds to step 310.

When the method 300 is comparing the DC+ power line 78 to the DC− power line 80 to determine the health of the electric vehicle charging adapter 22, at step 310, the method 300 compares the absolute value of the voltage measured across the first resistor 88 subtracted from the voltage measured across the second resistor 94 to a voltage threshold. When the voltage threshold is greater than the absolute value of the voltage measured across the first resistor 88 subtracted from the voltage measured across the second resistor 94, the method 300 then proceeds to step 312.

When the method 300 uses values stored within memory 68 to determine the health of the electric vehicle charging adapter 22, at step 310, the method 300 compares the voltage measured across the first resistor 88 and the voltage measured across the second resistor 94 to a range of acceptable voltage values in memory 68 for the specific electric vehicle charging adapter being tested. When the voltage measured across the first resistor 88 and the voltage measured across the second resistor 94 fall within the range of acceptable voltage values, the method 300 then proceeds to step 312.

At step 312, the first voltage supply 86 is enabled at a high current. The method 300 then proceeds to step 314.

At step 314, the first sensor 56 and the second sensor 58 measure the amperage across the first resistor 88 and the amperage across the second resistor 94 respectively. The method 300 then proceeds to step 316.

When the method 300 is comparing the amperage measured across the first resistor 88 and second resistor 94 to each other to determine the health of the electric vehicle charging adapter 22, at step 316, the method 300 compares the amperage measured by the first sensor 56 and the second sensor 58 to determine whether the measured amperages are equal. When the amperages are equal, the method 300 then proceeds to step 318.

When the method 300 uses values stored within memory 68 to determine the health of the electric vehicle charging adapter 22, at step 316, the method 300 compares the amperage measured across the first resistor 88 and the amperage measured across the second resistor 94 to a range of acceptable amperage values in memory 68 for the specific electric vehicle charging adapter being tested. When the amperage measured across the first resistor 88 and the amperage measured across the second resistor 94 fall within the range of acceptable amperage values, the method 300 then proceeds to step 318.

At step 318, the first sensor 56, second sensor 58, fourth sensor 62, and fifth sensor 64, measure the temperature of the electric vehicle charging adapter 22 and save the temperature to memory 68. The method 300 then proceeds to step 320.

At step 320, the timer 46 begins counting time in milliseconds. In an exemplary embodiment, the timer 46 stops counting time after 30 seconds have elapsed. It should be appreciated that the period of time the timer 46 counts can either be greater or less than the 30 seconds that is described in the current example. The method 300 then proceeds to step 322.

At step 322, a temperature threshold is determined by analyzing the amperage measured across the first resistor 88 and the amperage measured across the second resistor 94 in step 314 and the amount of time measured by the timer 46 the amperage measurements have remained consistent within a first margin of error to generate an expected temperature of the electric vehicle charging adapter 22. The method 300 then proceeds to step 324.

At step 324, the first sensor 56 and the second sensor 58 measure the temperature at the first resistor 88 and the temperature of the second resistor 94 respectively, and the fourth sensor 62 and the fifth sensor 64 measure the temperature at the first transistor 108 and the temperature at the second transistor 110 respectively. The method 300 then proceeds to step 326.

At step 326, the method 300 compares whether measured temperature increases between the temperatures measured by the first sensor 56, the second sensor 58, the fourth sensor 62, and the fifth sensor 64 after 30 seconds have elapsed on the timer 46 and the temperatures measured by the first sensor 56, the second sensor 58, the fourth sensor 62, and the fifth sensor 64 respectively are each greater than the temperature threshold. When none of the measured temperature increases are greater than the temperature threshold, the method 300 then proceeds to step 328.

At step 328, the electric vehicle adapter inspection device 24 determines that the health of the electric vehicle charging adapter 22 is “poor” and the red light from the plurality of signal lights 50 is lit.

Returning to step 326, when none of the measured temperature increases are greater than the temperature threshold, the method 300 then proceeds to step 330.

At step 330, the third sensor 60 measures the voltage across the fourth resistor 104 and then stores the measurement into memory 68. The method 300 then proceeds to step 332.

At step 332, heat is applied to the electric vehicle charging adapter 22 using the heating mechanism 47 until the internal temperature of the electric vehicle charging adapter 22 triggers the overtemperature charge current-limiting mechanism 37 37. The method 300 then proceeds to step 334.

At step 334, the third sensor 60 measures the voltage across the fourth resistor 104 and then stores the measurement into memory 68. The method 300 then proceeds to step 336.

At step 336, the voltage measurement measured from step 330 and the voltage measurement measured from step 334 are compared to determine whether the measured voltage from step 334 has shifted to a value less than the measured voltage in step 330 in order to verify whether the overtemperature charge current-limiting mechanism 37 37 was triggered. When the measured voltage from step 334 has shifted to a value less than the measured voltage from step 330, the method 300 then proceeds to step 338.

At step 338, the second voltage supply 96 is enabled at a low current. The method 300 then proceeds to step 340.

At step 340, the third sensor 60 measures the voltage across the third resistor 98 and the voltage across the fourth resistor 104. The method 300 then proceeds to step 342.

At step 342, the method 300 compares the value of the voltage measured across the third resistor 98 and the value of the voltage measured across the fourth resistor 104 are equal. When the voltage measured across the third resistor 98 and the voltage measured across the fourth resistor 104 are equal, the method 300 then proceeds to step 344.

At step 344, the electric vehicle adapter inspection device 24 determines that the health of the electric vehicle charging adapter 22 is “good” and the green light from the plurality of signal lights 50 is lit.

Returning to step 310, when the absolute value of the voltage measured across the first resistor 88 subtracted from the voltage measured across the second resistor 94 is greater than the voltage threshold, or when the measured voltage across the first resistor 88 and the second resistor 94 does not fall within the range of acceptable voltage values, the method 300 then proceeds to step 346.

At step 346, the electric vehicle adapter inspection device 24 determines that the health of the electric vehicle charging adapter 22 is “poor” and the red light from the plurality of signal lights 50 is lit.

Returning to step 316, when the amperage measured across the first resistor 88 and the amperage measured across the second resistor 94 are unequal, or when the measured amperage across the first resistor 88 and the second resistor 94 does not fall within the range of amperage voltage values, the method 300 then proceeds to step 348.

At step 348, the electric vehicle adapter inspection device 24 determines that the health of the electric vehicle charging adapter 22 is “poor” and the red light from the plurality of signal lights 50 is lit.

Returning to step 336, when the measured voltage from step 334 has not shifted, or has shifted to a value greater than the measured voltage from step 330, the method 300 proceeds to step 350.

At step 350, the electric vehicle adapter inspection device 24 determines that the health of the electric vehicle charging adapter 22 is “poor” because the overtemperature charge current-limiting mechanism 37 37 did not trigger and the red light from the plurality of signal lights 50 is lit.

Returning to step 342, when the voltage measured across the third resistor 98 and the voltage measured across the fourth resistor 104 are unequal, the method 300 then proceeds to step 350.

At step 352, the electric vehicle adapter inspection device 24 determines that the health of the electric vehicle charging adapter 22 is “poor” and the red light from the plurality of signal lights 50 is lit.

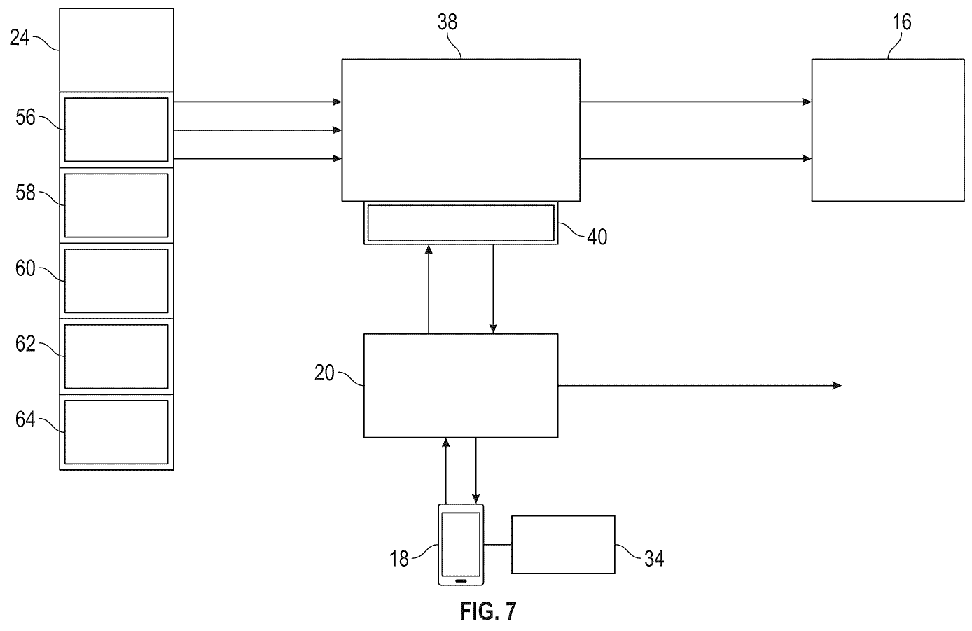

Referring to FIG. 7, a diagram showing how the electric vehicle adapter inspection device 24 communicates with the external device 18 and the rental unit enclosure 16 is generally indicated by reference number 112. It should be appreciated that the exemplary embodiment represents the electric vehicle adapter inspection device 24 when powered by a high voltage direct current.

The external device 18 may be used to communicate a user request, which is a request to release the electric vehicle charging adapter 22 from the rental unit enclosure 16 to be used for the charging of the vehicle 12, to the back-office computing platform 20. The external device 18 may also be used to communicate images taken by the camera 34 of the electric vehicle charging adapter 22 to determine the optical health of the electric vehicle charging adapter 22 to the back-office computing platform 20. The images may be taken both before and after the electric vehicle charging adapter 22 is used for charging the vehicle 12. The external device 18 may also receive billing information from the back-office computing platform 20. The billing information may include the cost of the use of the electric vehicle charging adapter 22 for charging the vehicle 12, as well as the cost of damage to the electric vehicle charging adapter 22 detected by the controller 38, including the cost of replacing parts of or the entirety of the electric vehicle charging adapter 22. The external device 18 may also communicate payment information for the payment of the cost of the billing information to the back-office computing platform 20.

The back-office computing platform 20 may be used to communicate billing information to the external device 18. The back-office computing platform 20 may also be used to communicate the user request, payment information, and images for determining the optical health of the electric vehicle charging adapter 22 from the external device 18 to the cellular transceiver 40. The back-office computing platform 20 may also communicate the results of its analysis of the optical health determination of the electric vehicle charging adapter 22 based on the images taken of the electric vehicle charging adapter 22 to the cellular transceiver 40. The back-office computing platform 20 may receive the images taken of the electric vehicle charging adapter 22, the billing information, and the results of the electric vehicle adapter inspection device's 24 determination of the health of the electric vehicle charging adapter 22 from the cellular transceiver 40. The back-office computing platform 20 may also generate an email or text message communication to maintenance personnel for the repair or replacement of the electric vehicle charging adapter 22 when the electric vehicle adapter inspection device 24 determines the health of the electric vehicle charging adapter 22 is “poor”.

The controller 38 receives voltage, amperage, and temperature measurements from the first sensor 56, the second sensor 58, the third sensor 60, the fourth sensor 62, and the fifth sensor 64 via the input and output ports 70 to determine the health of the electric vehicle charging adapter 22. The controller 38 communicates the results of the determination of the health of the electric vehicle charging adapter 22 to the rental unit enclosure 16 to light one of the plurality of signal lights 50 based on the results. The controller 38 also communicates the user request to the rental unit enclosure 16 so the rental unit enclosure 16 deactivates the locking actuator of the door 33 so that the electric vehicle charging adapter 22 may be removed from the rental unit enclosure 16.

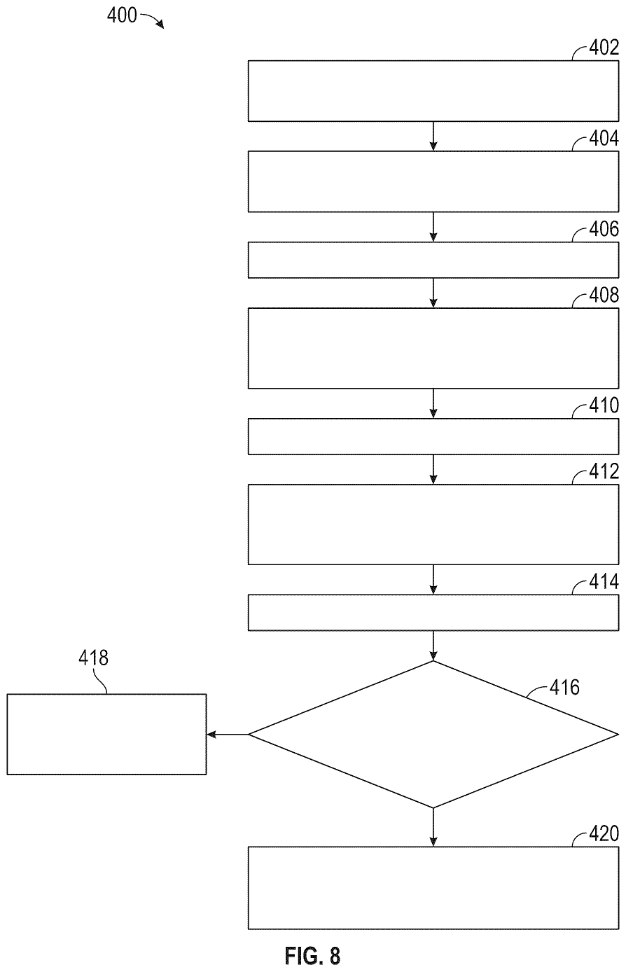

Referring to FIG. 8, a flowchart for a method of determining the health of an electric vehicle charging adapter 22 using the electric vehicle adapter inspection device 24 within the rental unit enclosure 16 is generally indicated by reference number 400. The method 400 begins at step 402, when a customer uses the external device 18 to send a user request to the controller 38 and having the controller 38 deactivate the locking actuator of the door 33 of the rental unit enclosure 16. The method 400 then proceeds to step 404.

At step 404, the customer opens the door 33 and disconnects the coupler 44 from the back of the electric vehicle charging adapter 22, marking the electric vehicle charging adapter 22 temporarily unavailable on the human-machine interface to other customers who may attempt to communicate a user request to the controller 38 to use the electric vehicle charging adapter 22. The method 400 then proceeds to step 406.

At step 406, the customer manually disconnects the electric vehicle charging adapter 22 from the inlet 42. The method 400 then proceeds to step 408.

At step 408, the customer uses the camera 34 to take images of the four sides of the electric vehicle charging adapter 22, which are then communicated to the back-office computing platform 20 to be analyzed by an artificial intelligence algorithm to determine the optical health of the electric vehicle charging adapter 22. The method 400 then proceeds to step 410.

At step 410, the customer uses the electric vehicle charging adapter 22 to charge the vehicle 12. The method 400 then proceeds to step 412.

At step 412, the customer uses the camera 34 to take images of the four sides of the electric vehicle charging adapter 22, which are then communicated to the back-office computing platform 20 to be analyzed by an artificial intelligence algorithm to determine the optical health of the electric vehicle charging adapter 22. The method 400 then proceeds to step 414.

At step 414, the customer attaches the electric vehicle charging adapter 22 to the inlet 42. The method 400 then proceeds to step 416.

At step 416, the customer closes the door 33 of the rental unit enclosure 16, and the method 200 is executed when the electric vehicle adapter inspection device 24 is powered by a low voltage direct current or the method 300 is executed when the electric vehicle adapter inspection device is powered by a high voltage direct current to determine the health of the electric vehicle charging adapter 22. The results of either the method 200 or method 300 and the results of the analysis of the images taken of the electric vehicle charging adapter 22 in step 408 and step 412. When the health of the electric vehicle charging adapter 22 is “good”, the method 400 then proceeds to step 418.

At step 418, billing information is communicated from the controller 38 to the external device 18 for the use of the electric vehicle charging adapter 22 and the electric vehicle charging adapter 22 is marked as available on the human-machine interface for use from other customers.

Returning to step 416, when the health of the electric vehicle charging adapter 22 is “poor”, the method 400 then proceeds to step 420.

At step 420, billing information is communicated from the controller 38 to the external device 18 for the cost of the damage to the electric vehicle charging adapter 22 and the back-office computing platform sends a communication to maintenance personnel to either repair or replace the electric vehicle charging adapter 22.

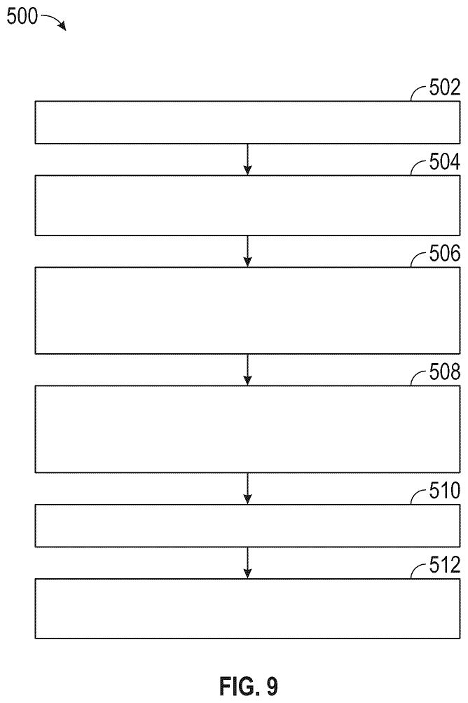

Referring to FIG. 9, a flowchart for a method of determining the health of the electric vehicle charging adapter 22 using the charging station 14 is generally indicated by reference number 500. The method 500 begins at step 502, when a customer selects a “test adapter” option from the human-machine interface of either the external device 18 or the charging station 14. The method 500 then proceeds to step 504.

At step 504, the customer attaches the electric vehicle charging adapter 22 to the coupler 44 and the inlet 42, completing a circuit. The method 500 then proceeds to step 506.

At step 506, the customer initiates a request for the electric vehicle adapter inspection device 24 within the charging station 14 to determine the health of the electric vehicle charging adapter 22. The request may be initiated via the external device 18 or the screen for display in the charging station 14. The method 500 then proceeds to step 508.

At step 508, the method 200 is executed when the electric vehicle adapter inspection device 24 is powered by a low voltage direct current or the method 300 is executed when the electric vehicle adapter inspection device is powered by a high voltage direct current to determine the health of the electric vehicle charging adapter 22. The method 500 then proceeds to step 510.

At step 510, either the external device 18 or the charging station's 14 display screen, depending on which was used to request the determination of the health of the electric vehicle charging adapter 22, informs the customer whether the health of the electric vehicle charging adapter 22 is “good” or “poor”. When the health of the electric vehicle charging adapter 22 is “poor”, the method 500 proceeds to step 512.

At step 512, either the external device 18 or the charging station's 14 display screen, depending on which was used to request the determination of the health of the electric vehicle charging adapter 22, provides the customer with instructions on how to proceed.

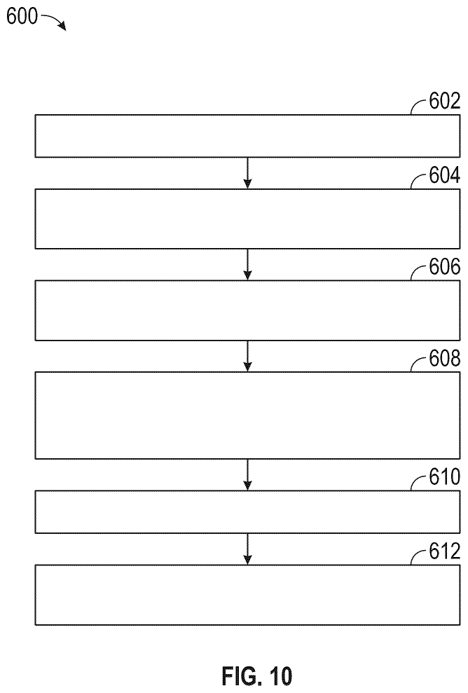

Referring to FIG. 10, a flowchart for a method of determining the health of the electric vehicle charging adapter 22 using the vehicle 12 is generally indicated by reference number 600. The method 600 begins at step 602, when a customer selects a “test adapter” option from the human-machine interface of either the external device 18 or the vehicle 12. The method 600 then proceeds to step 604.

At step 604, the customer attaches the charging station coupler 28 to the vehicle-side of the electric vehicle charging adapter 22 and attaches the electric vehicle charging adapter 22 to the vehicle inlet 26, completing a circuit. The method 600 then proceeds to step 606.

At step 606, the customer initiates a request for the go/no-go mechanism 48 within the vehicle 12 to determine the health of the electric vehicle charging adapter 22. The request may be initiated via the external device 18 or the screen for display in the vehicle 12. The method 600 then proceeds to step 608.

At step 608, the method 200 is executed when the electric vehicle adapter inspection device 24 is powered by a low voltage direct current or the method 300 is executed when the electric vehicle adapter inspection device is powered by a high voltage direct current to determine the health of the electric vehicle charging adapter 22. The method 600 then proceeds to step 610.

At step 610, either the external device 18 or the vehicle's 12 display screen, depending on which was used to request the determination of the health of the electric vehicle charging adapter 22, informs the customer whether the health of the electric vehicle charging adapter 22 is “good” or “poor”. When the health of the electric vehicle charging adapter 22 is “poor”, the method 600 proceeds to step 612.

At step 612, either the external device 18 or the vehicle's 12 display screen, depending on which was used to request the determination of the health of the electric vehicle charging adapter 22, provides the customer with instructions on how to proceed.

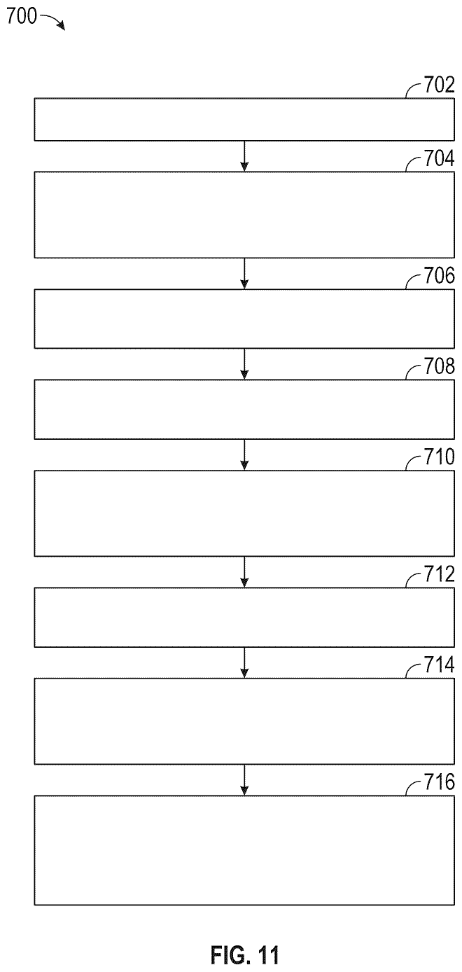

Referring to FIG. 11, a flowchart for a method of determining the health of the electric vehicle charging adapter 22 using the electric vehicle adapter inspection device 24 as a standalone device is generally indicated by reference number 700. The method 700 begins with step 702, when a user powers the electric vehicle adapter inspection device 24 on by pressing the power button 52. In a non-limiting list of examples, the user can be an employee of a vehicle-testing laboratory, an auto dealer, an auto parts store, or a fleet depot. The method 700 then proceeds to step 704.

At step 704, the user uses the camera 34 to take images of the four sides of the electric vehicle charging adapter 22, which are then communicated to the back-office computing platform 20 to be analyzed by an artificial intelligence algorithm to determine the optical health of the electric vehicle charging adapter 22. It should be appreciated that step 704 is an optional step and is not mandatory for the completion of the method 700. The method 700 then proceeds to step 706.

At step 706, the user attaches the coupler 44 to the vehicle-side of the electric vehicle charging adapter 22 and attaches the charging station-side of the electric vehicle charging adapter 22 to the inlet 42. The method 700 then proceeds to step 708.

At step 708, the user presses the “initiate test” button 54 on the electric vehicle adapter inspection device 24. The method 700 then proceeds to step 710.

At step 710, the method 200 is executed when the electric vehicle adapter inspection device 24 is powered by a low voltage direct current or the method 300 is executed when the electric vehicle adapter inspection device is powered by a high voltage direct current to determine the health of the electric vehicle charging adapter 22. The method 700 then proceeds to step 712.

At step 712, the user detaches the coupler 44 from the electric vehicle charging adapter 22 and detaches the electric vehicle charging adapter 22 from the inlet 42. The method 700 then proceeds to step 714.

At step 714, the user uses the camera 34 to take images of the four sides of the electric vehicle charging adapter 22, which are then communicated to the back-office computing platform 20 to be analyzed by an artificial intelligence algorithm to determine the optical health of the electric vehicle charging adapter 22. It should be appreciated that step 714 is an optional step and is not mandatory for the completion of the method 700. The method 700 then proceeds to step 716.

At step 716, the health of the electric vehicle charging adapter 22 is determined by incorporating the results of either the executed method 200 or method 300 and the results of the analysis of the images taken of the electric vehicle charging adapter 22 in step 704 and step 714 if those steps are followed. The determination is indicated using the plurality of signal lights 50.

The electric vehicle adapter inspection device 24 of the present disclosure offers several advantages. These include an increased accessibility of the electric vehicle charging adapter 22, an increased security of the electric vehicle charging adapter 22, and a greater ability to track damage inflicted upon the electric vehicle charging adapter 22 while also a more efficient ability to repair or replace the electric vehicle charging adapter 22.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. An electric vehicle adapter inspection device for determining the health of an electric vehicle charging adapter, the electric vehicle adapter inspection device comprising:
an inlet wherein a charging station-side of the electric vehicle charging adapter is attached;
a coupler that is attached to a vehicle-side of the electric vehicle charging adapter; and
a go/no-go mechanism for determining the health of the electric vehicle charging adapter.

2. The electric vehicle adapter inspection device of claim 1, wherein the electric vehicle charging adapter is attached to the inlet and the coupler to complete a circuit.

3. The electric vehicle adapter inspection device of claim 1, wherein the inlet further comprises a first sensor, a second sensor, and a third sensor.

4. The electric vehicle adapter inspection device of claim 3, wherein the first sensor and the second sensor are voltage sensors when the electric vehicle adapter inspection device is powered by a low voltage direct current.

5. The electric vehicle adapter inspection device of claim 3, wherein the first sensor and the second sensor are voltage sensors, ammeters, and temperature sensors when the electric vehicle adapter inspection device is powered by a high voltage direct current.

6. The electric vehicle adapter inspection device of claim 5, wherein the coupler further comprises a fourth sensor and a fifth sensor that are both temperature sensors.

7. The electric vehicle adapter inspection device of claim 3, wherein the third sensor has voltage sensor functionality when the electric vehicle adapter inspection device is powered by a low voltage direct current and a high voltage direct current.

8. The electric vehicle adapter inspection device of claim 4, wherein the health of the electric vehicle charging adapter is determined to be “good” by the go/no-go mechanism when the absolute value of a voltage measured across a second resistor by the second sensor subtracted from a voltage measured across a first resistor by the first sensor is less than or equal to a voltage threshold.

9. The electric vehicle adapter inspection device of claim 4, wherein the health of the electric vehicle charging adapter is determined to be “good” by the go/no-go mechanism when a voltage measured across a first resistor by the first sensor and a voltage measured across a second resistor by the second sensor fall within a range of acceptable voltage values for a specific electric vehicle charging adapter within memory in the electric vehicle adapter inspection device.

10. The electric vehicle adapter inspection device of claim 5, wherein the health of the electric vehicle charging adapter is determined to be “good” by the go/no-go mechanism when an amperage measured across a first resistor by the first sensor is equal to an amperage measured across a second resistor by the second sensor.

11. The electric vehicle adapter inspection device of claim 5, wherein the health of the electric vehicle charging adapter is determined to be “good” by the go/no-go mechanism when an amperage measured across a first resistor by the first sensor and an amperage measured across a second resistor by the second sensor fall within a range of acceptable amperage values for a specific electric vehicle charging adapter within memory in the electric vehicle adapter inspection device.

12. The electric vehicle adapter inspection device of claim 6, wherein the health of the electric vehicle charging adapter is determined to be “good” by the go/no-go mechanism when measured temperature increases of the electric vehicle charging adapter by the first sensor, the second sensor, the fourth sensor, and the fifth sensor respectively are all less than or equal to a temperature threshold.

13. The electric vehicle adapter inspection device of claim 3, wherein the health of the electric vehicle charging adapter is determined to be “good” by the go/no-go mechanism when a voltage measured across a third resistor and a voltage measured across a fourth resistor by the third sensor are equal.

14. The electric vehicle adapter inspection device of claim 6, wherein the health of the electric vehicle charging adapter is determined to be “good” by the go/no-go mechanism when a voltage measured across a fourth resistor by the third sensor after a heating mechanism heats the electric vehicle charging adapter to a temperature that allows a overtemperature charge current-limiting mechanism 37 disposed within the electric vehicle charging adapter to trigger shifts to a value that is less than a voltage measured across the fourth resistor by the third sensor before the heating mechanism heats the electric vehicle charging adapter to verify that the overtemperature charge current-limiting mechanism 37 has triggered.

15. The electric vehicle adapter inspection device of claim 1, wherein the electric vehicle adapter inspection device is disposed within an electric vehicle.

16. The electric vehicle adapter inspection device of claim 1, wherein the electric vehicle adapter inspection device is disposed within a rental unit enclosure.

17. The electric vehicle adapter inspection device of claim 1, wherein the electric vehicle adapter inspection device is disposed within a charging station.

18. An electric vehicle adapter inspection device for determining the health of an electric vehicle charging adapter, the electric vehicle adapter inspection device comprising:
an inlet wherein a charging station-side of the electric vehicle charging adapter is attached comprising a first sensor, a second sensor, and a third sensor that are voltage sensors;
a coupler that is attached to a vehicle-side of the electric vehicle charging adapter;
a go/no-go mechanism for determining the health of the electric vehicle charging adapter;
a plurality of signal lights that indicate the health of the electric vehicle charging adapter based on the determination of health of the electric vehicle charging adapter by the go/no-go mechanism;
wherein the electric vehicle adapter inspection device is powered by a low voltage direct-current electric current; and
wherein the health of the electric vehicle charging adapter is determined to be “good” by the go/no-go mechanism when the absolute value of a voltage measured across a second resistor by the second sensor subtracted from a voltage measured across a first resistor by the first sensor is less than or equal to a voltage threshold or a voltage measured across the first resistor by the first sensor and a voltage measured across the second resistor by the second sensor fall within a range of acceptable voltage values for a specific electric vehicle charging adapter within memory in the electric vehicle adapter inspection device.

19. An electric vehicle adapter inspection device for determining the health of an electric vehicle charging adapter, the electric vehicle adapter inspection device comprising:
an inlet wherein a charging station-side of the electric vehicle charging adapter is attached comprising a first sensor and a second sensor are voltage sensors, ammeters, and temperature sensors;
the inlet further comprising a third sensor that is a voltage sensor;
a coupler that is attached to a vehicle-side of the electric vehicle charging adapter comprising a fourth sensor and a fifth sensor that are temperature sensors;
a go/no-go mechanism for determining the health of the electric vehicle charging adapter;
a plurality of signal lights that indicate the health of the electric vehicle charging adapter based on the determination of health of the electric vehicle charging adapter by the go/no-go mechanism;
wherein the health of the electric vehicle charging adapter is determined to be “good” by the go/no-go mechanism when the absolute value of a voltage measured across a second resistor by the second sensor subtracted from a voltage measured across a first resistor by the first sensor is less than or equal to a voltage threshold, an amperage measured across the first resistor by the first sensor is equal to an amperage measured across the second resistor by the second sensor, measured temperature increases of the electric vehicle charging adapter measured by the first sensor, the second sensor, the fourth sensor, and the fifth sensor are all less than or equal to a temperature threshold, a voltage measured across a third resistor and a voltage measured across a fourth resistor by the third sensor are equal, and a voltage measured across the fourth resistor by the third sensor after a heating mechanism heats the electric vehicle charging adapter to a temperature that allows a overtemperature charge current-limiting mechanism disposed within the electric vehicle charging adapter to trigger shifts to a value that is less than a voltage measured across the fourth resistor by the third sensor before the heating mechanism heats the electric vehicle charging adapter to verify that the overtemperature charge current-limiting mechanism has triggered; and
wherein the electric vehicle adapter inspection device is powered by a high voltage direct-current electric current.

20. The electric vehicle adapter inspection device of claim 19, wherein the electric vehicle adapter inspection device is disposed within an electric vehicle.
